(19) United States
(12) Patent Application Publication
(10) Pub. No.: US 2021/0050493 A1
(43) Pub. Date: Feb. 18, 2021

(54) Optoelectronic Semiconductor Device and Method for Producing an Optoelectronic Semiconductor Device

(71) Applicant: OSRAM Opto Semiconductors GmbH, Regensburg (DE)

(72) Inventors: Jun Jun Lim, Melaka (MY); Sok Gek Beh, Penang (MY); Mohd Fauzi Zainordin, Penang (MY); Purusothaman Supramaniam, Penang (MY)

(21) Appl. No.: 16/979,677

(22) PCT Filed: Mar. 12, 2018
(86) PCT No.: PCT/EP2018/056030

§ 371 Date: Sep. 10, 2020

(51) Int. Cl. H01L 33/58; H01L 33/48; H01S 5/022; H01S 5/02

(52) U.S. Cl. CPC H01L 33/58; H01L 33/486; H01L 33/62; H01S 5/0216; H01L 2933/0058; H01S 5/02288

(57) ABSTRACT

An optoelectronic semiconductor device and a method for producing an optoelectronic semiconductor device are disclosed. In an embodiment an optoelectronic semiconductor device includes a carrier having at least two electrically conductive components connected by an electrically insulating material, an optoelectronic semiconductor chip fixed to the carrier at a top side of the carrier, the optoelectronic semiconductor chip configured to emit electromagnetic radiation, a total internal reflection lens and a housing surrounding the total internal reflection lens laterally, wherein the electrically insulating material does not protrude over the electrically conductive components at the top side of the carrier, wherein the housing and the total internal reflection lens are arranged at a radiation exit side of the optoelectronic semiconductor chip, and wherein the total internal reflection lens does not protrude over the housing at an upper side of the optoelectronic semiconductor device, the upper side facing away from the carrier.

This patent application is a national phase filing under section 371 of PCT/EP2018/056030, filed Mar. 12, 2018, of which is incorporated herein by reference in its entirety.

### TECHNICAL FIELD

An optoelectronic semiconductor device and a method for producing an optoelectronic semiconductor device are provided.

### SUMMARY

Embodiments provide an optoelectronic semiconductor device with improved optical properties. Further embodiments provide a method for producing an optoelectronic semiconductor device with improved optical properties.

In at least one embodiment of the optoelectronic semiconductor device, the optoelectronic semiconductor device comprises a carrier which comprises at least two electrically conductive components that are connected by an electrically insulating material. The carrier can have a main plane of extension. The carrier extends further within the main plane of extension than in other directions. The carrier is adapted for mechanically supporting further components of the optoelectronic semiconductor device.

The electrically conductive components can comprise an electrically conductive material, as for example a metal. The at least two electrically conductive components can be electrically isolated against each other via the electrically insulating material. This means, the at least two electrically conductive components are not in direct contact with each other. The electrically insulating material can comprise an epoxy molding compound.

In at least one embodiment the optoelectronic semiconductor device comprises an optoelectronic semiconductor chip which is fixed to the carrier at a top side of the carrier and which is configured to emit electromagnetic radiation during operation of the optoelectronic semiconductor device. The optoelectronic semiconductor chip can for example be a light-emitting diode or a laser. The semiconductor chip can be configured to emit electromagnetic radiation within a specified wavelength range during operation of the optoelectronic semiconductor device. For example, the optoelectronic semiconductor chip can emit light or electromagnetic radiation in the visible range.

Preferably, electromagnetic radiation emitted by the optoelectronic semiconductor chip leaves the optoelectronic semiconductor chip at a radiation exit side where the radiation exit side of the optoelectronic semiconductor chip faces away from the carrier. The optoelectronic semiconductor chip can be in direct contact with the carrier. The optoelectronic semiconductor chip can be electrically contacted by a bonding wire. This means, the optoelectronic semiconductor chip can be electrically contacted at the radiation exit side of the optoelectronic semiconductor chip by a bonding wire which is connected to the carrier.

In at least one embodiment the optoelectronic semiconductor device comprises a total internal reflection lens. The total internal reflection lens can be configured to shape the electromagnetic radiation emitted by the optoelectronic semiconductor chip during operation by total internal reflection. The total internal reflection lens can comprise a material which has a refractive index which is larger than one and in particular larger than the refractive index of a surrounding material like air.

Furthermore, the total internal reflection lens can comprise a material which is at least partially transparent for the electromagnetic radiation emitted by the optoelectronic semiconductor chip. The electromagnetic radiation emitted by the optoelectronic semiconductor chip can be shaped by the total internal reflection lens in such a way that the optoelectronic semiconductor device is configured to emit electromagnetic radiation during operation mainly in one direction. This means, the opening angle of the electromagnetic radiation emitted by the optoelectronic semiconductor device during operation can for example be smaller than 40°. Thus, the optoelectronic semiconductor device can be configured to emit electromagnetic radiation during operation mainly in a vertical direction which is perpendicular to the main plane of extension of the carrier. As electromagnetic radiation emitted by the optoelectronic semiconductor chip can be shaped by the total internal reflection lens in such a way that the optoelectronic semiconductor device is configured to emit electromagnetic radiation during operation mainly in one direction, the total internal reflection lens can be configured to provide the optical function of a reflector.

In at least one embodiment the optoelectronic semiconductor device comprises a housing which surrounds the total internal reflection lens laterally. The housing can comprise a recess in which the total internal reflection lens is arranged. That the housing surrounds the total internal reflection lens laterally can mean that the housing surrounds the total internal reflection lens in lateral directions which are parallel to the main plane of extension of the carrier, e.g., completely. The housing can act as a frame which surrounds the total internal reflection lens in lateral directions. Thus, the total internal reflection lens can be arranged within the housing. The housing can comprise side surfaces which extend in the vertical direction or are inclined with respect to the vertical direction. The side surfaces of the housing can be outer surfaces of the optoelectronic semiconductor device.

The housing can be arranged and fixed on the carrier. The housing can be arranged and fixed at the top side of the carrier. For example, the housing can be glued to the carrier. This means, a glue or adhesive can be arranged between the housing and the carrier.

In at least one embodiment the electrically insulating material does not protrude over the electrically conductive components at the top side of the carrier. This can mean that the electrically insulating material does not extend further in the vertical direction than the electrically conductive components. It is possible that the electrically insulating material and the electrically conductive components terminate flush at the top side of the carrier. It is further possible that the electrically conductive components extend further in vertical direction at the top side of the carrier than the electrically insulating material. This means, the electrically conductive components can protrude over the electrically insulating material at the top side. The electrically insulating material can be arranged next to the electrically conductive components in a lateral direction. The electrically insulating material can extend from a bottom side of the carrier which faces away from the top side to the top side of the carrier. Furthermore, the electrically conductive components can extend from the bottom side of the carrier to the top side of the carrier.

The optoelectronic semiconductor chip can be arranged on one of the electrically conductive components. This means, the optoelectronic semiconductor chip can be in direct contact with one of the electrically conductive components. The bonding wire can electrically connect the optoelectronic semiconductor chip with the other electrically conductive component on which the optoelectronic semiconductor chip is not arranged.

In at least one embodiment the housing and the total internal reflection lens are arranged at a radiation exit side of the optoelectronic semiconductor chip. The radiation exit side of the optoelectronic semiconductor chip can be the side of the optoelectronic semiconductor chip where electromagnetic radiation is emitted during operation of the optoelectronic semiconductor device. The radiation exit side of the optoelectronic semiconductor chip can for example be arranged at the side of the optoelectronic semiconductor chip which faces away from the carrier.

The housing and the total internal reflection lens can be arranged in such a way that the optoelectronic semiconductor chip is completely covered by the housing and the total internal reflection lens. The total internal reflection lens can surround the optoelectronic semiconductor chip laterally. It is further possible that the housing surrounds the optoelectronic semiconductor chip laterally. In this way, the optoelectronic semiconductor chip and the bonding wire are protected by the housing.

The total internal reflection lens can be spaced from the optoelectronic semiconductor chip such that the total internal reflection lens and the optoelectronic semiconductor chip are not in direct contact with each other. Thus, electromagnetic radiation emitted by the optoelectronic semiconductor chip during operation can enter the total internal reflection lens from a medium, for example air, which has a refractive index which is smaller than the refractive index of the total internal reflection lens. Furthermore, the total internal reflection lens can be at least partially surrounded by a material with a refractive index which is smaller than the refractive index of the total internal reflection lens in lateral directions. Therefore, electromagnetic radiation impinging at an interface between the total internal reflection lens and a medium with a smaller refractive index, as for example air, under a range of angles is reflected within the total internal reflection lens in the direction of an upper side of the optoelectronic semiconductor device where the upper side faces away from the carrier. Therefore, no reflecting materials are required in order to reflect electromagnetic radiation emitted by the optoelectronic semiconductor chip in the direction of the upper side of the optoelectronic semiconductor device.

In at least one embodiment the total internal reflection lens does not protrude over the housing at an upper side of the optoelectronic semiconductor device, where the upper side faces away from the carrier. This can mean that the total internal reflection lens does not extend further in the vertical direction than the housing. The housing can extend further in the vertical direction than the total internal reflection lens. This means the housing can protrude over the total internal reflection lens at the upper side of the optoelectronic semiconductor device. It is further possible that the housing and the total internal reflection lens have the same extent in the vertical direction. This means, the housing and the total internal reflection lens can terminate flush at the upper side of the optoelectronic semiconductor device. The upper side of the optoelectronic semiconductor device can be a radiation exit side of the optoelectronic semiconductor device.

In at least one embodiment the optoelectronic semiconductor device comprises a carrier which comprises at least two electrically conductive components that are connected by an electrically insulating material, an optoelectronic semiconductor chip which is fixed to the carrier at a top side of the carrier and which is configured to emit electromagnetic radiation during operation of the optoelectronic semiconductor device, a total internal reflection lens, and a housing which surrounds the total internal reflection lens laterally. The electrically insulating material does not protrude over the electrically conductive components at the top side of the carrier, the housing and the total internal reflection lens are arranged at a radiation exit side of the optoelectronic semiconductor chip and the lens does not protrude over the housing at an upper side of the optoelectronic semiconductor device, where the upper side faces away from the carrier.

For common optoelectronic semiconductor devices a reflector is mounted on the carrier of the device. The reflector comprises reflecting sidewalls which can be coated with a metal layer. The optoelectronic semiconductor chip of the devise can be arranged in a recess of the reflector. A lens can be mounted on top of the reflector, for example by gluing. Due to the exposed position the lens is sensitive towards shear forces which can arise during production steps or mounting steps. Furthermore, the area for gluing is limited which results in a low adhesion between the lens and the reflector. Thus, the shear forces can lead to a misalignment or delamination of the lens.

For the optoelectronic semiconductor device described herein the housing laterally surrounds the total internal reflection lens. This means, the total internal reflection lens is arranged within the housing. Therefore, the total internal reflection lens is more protected from shear forces. As the total internal reflection lens does not protrude over the housing, the total internal reflection lens is protected from shear forces by the housing in lateral directions. Furthermore, the adhesion between the total internal reflection lens and the housing can be improved. A misalignment or delamination of the total internal reflection lens is avoided since the total internal reflection lens is laterally surrounded by the housing. Moreover, the stability of the whole optoelectronic semiconductor device is increased by arranging the total internal reflection lens within the housing.

Furthermore, the alignment of the total internal reflection lens with respect to the optoelectronic semiconductor chip can be improved as only one alignment step is required in the production process, namely the positioning of the housing with the total internal reflection lens on the carrier. For an increased number of alignment steps the probability for misalignment can increase. Consequently, as only one alignment step is required, the optical consistency of the electromagnetic radiation emitted by the optoelectronic semiconductor device during operation is improved. This means, the optical properties of the optoelectronic semiconductor device are improved.

In addition, the carrier employed for the optoelectronic semiconductor device described herein has a low thermal resistance such that heat can be efficiently transferred from the optoelectronic semiconductor chip to the bottom side of the carrier.

Advantageously, for the optoelectronic semiconductor device described herein no reflecting layer comprising for example a metal is required in order to reflect electromagnetic radiation emitted by the optoelectronic semiconductor chip in the direction of the upper side of the optoelectronic semiconductor device. Instead of employing a reflecting layer the total internal reflection lens is arranged within the housing.

In at least one embodiment the total internal reflection lens is monolithically integrated with the housing. This can mean that the total internal reflection lens forms an integral part of the housing. The total internal reflection lens and the housing can be integrally connected with each other. It is further possible that the total internal reflection lens and the housing are connected with each other in such a way that they cannot be separated without destroying at least one of them. The total internal reflection lens and the housing can be connected by a glue. Advantageously, since the total internal reflection lens is monolithically integrated with the housing, the alignment of the total internal reflection lens with respect to the optoelectronic semiconductor chip is simplified. The total internal reflection lens is arranged within the housing and protected by the housing, and therefore only one alignment step is required, namely when the housing is positioned on the carrier. The less alignment steps are required, the less errors can occur during alignment. If the total internal reflection lens and the optoelectronic semiconductor chip are aligned, the optical properties of the optoelectronic semiconductor device are improved.

In at least one embodiment electromagnetic radiation emitted by the optoelectronic semiconductor chip only leaves the optoelectronic semiconductor device at the upper side. Electromagnetic radiation emitted by the optoelectronic semiconductor chip in the direction of the upper side of the optoelectronic semiconductor device can pass through the total internal reflection lens and leave the optoelectronic semiconductor device at the upper side. Electromagnetic radiation emitted by the optoelectronic semiconductor chip in directions which are different from the vertical direction can be reflected by the total internal reflection lens in the direction of the upper side. The sidewalls of the housing and the carrier can be at least partially opaque. Consequently, electromagnetic radiation emitted by the optoelectronic semiconductor chip only leaves the optoelectronic semiconductor device at the upper side. For many applications it is desired that electromagnetic radiation emitted by an optoelectronic semiconductor device leaves the optoelectronic semiconductor device only at one side. Furthermore, since the electromagnetic radiation emitted by the optoelectronic semiconductor chip only leaves the optoelectronic semiconductor device at the upper side the opening angle of the emitted electromagnetic radiation can be small.

In at least one embodiment the total internal reflection lens comprises outer surfaces which are at least partially inclined with respect to the main plane of extension of the carrier. This means, the outer surfaces are at least in places not parallel to the main plane of extension of the carrier. It is further possible that the outer surfaces are at least in places not parallel to the vertical direction. The outer surfaces can be inclined in such a way that a cross section of the total internal reflection lens increases from the carrier towards the upper side, where the cross section is given in a plane which is parallel to the main plane of extension of the carrier. Advantageously, in this way electromagnetic radiation emitted by the optoelectronic semiconductor chip during operation can be shaped by total internal reflection when passing through the total internal reflection lens.

In at least one embodiment at least a part of a radiation exit surface of the total internal reflection lens is spherical, aspherical or elliptical. By employing a radiation exit surface which is not flat but at least partially spherical, aspherical or elliptical the electromagnetic radiation leaving the optoelectronic semiconductor device can be further collimated. In this case the housing can protrude over the total internal reflection lens in order to protect the total internal reflection lens.

In at least one embodiment the carrier comprises a leadframe. The two electrically conductive components of the carrier can form the leadframe. The lead frame can comprise copper. The carrier can for example comprise a quad flat no leads package. The carrier comprising the leadframe can be very thin and cheap.

In at least one embodiment a side surface of the housing terminates flush with a side surface of the carrier. The side surfaces of the carrier can extend in vertical direction. The housing can be arranged on the carrier in such a way that for at least one side surface of the housing, the housing terminates flush with a side surface of the carrier and the housing does not protrude over the carrier in at least one lateral direction. It is further possible that each side surface of the housing terminates flush with one side surface of the carrier, respectively. This means, the housing is aligned with the carrier. For further processing steps or for mounting it is advantageous if the side surfaces of the housing terminate flush with the respective side surface of the carrier.

In at least one embodiment the housing is fixed to the carrier by a glue. The glue can be arranged between the housing and the carrier in the vertical direction. The glue can be arranged on the top side of the carrier along at least one side surface of the carrier. It is further possible that the glue is arranged on the top side of the carrier along each side surface of the carrier. The glue can be arranged in the shape of a frame which surrounds the optoelectronic semiconductor chip laterally, e.g., completely. Thus the area of the glue can be particularly large which supports a strong mechanical connection between the carrier and the housing. Advantageously, only one step for aligning the total internal reflection lens with respect to the optoelectronic semiconductor chip is required as the housing with the total internal reflection lens is glued to the carrier.

In at least one embodiment the total internal reflection lens comprises or consists of an epoxy resin. The epoxy resin can be transparent for the electromagnetic radiation emitted by the optoelectronic semiconductor chip during operation. Furthermore, the refractive index of the epoxy resin can be larger than the refractive index of air. Consequently, the total internal reflection lens is configured to shape the electromagnetic radiation emitted by the optoelectronic semiconductor chip during operation by total internal reflection.

In at least one embodiment the total internal reflection lens comprises or consists of a plastic material. The plastic material can be transparent for the electromagnetic radiation emitted by the optoelectronic semiconductor chip during operation. Furthermore, the refractive index of the plastic material can be larger than the refractive index of air. Consequently, the total internal reflection lens is configured to shape the electromagnetic radiation emitted by the optoelectronic semiconductor chip during operation by total internal reflection.

In at least one embodiment the opening angle of a beam of electromagnetic radiation emitted by the optoelectronic semiconductor device during operation is smaller than 30°. The opening angle refers to the opening angle of the electromagnetic radiation leaving the optoelectronic semiconductor device at the upper side. Thus, the optoelectronic semiconductor device can be employed for applications which require a small opening angle of the emitted electromagnetic radiation, as for example for iris recognition. A similar optoelectronic semiconductor device, which is suitable for iris recognition, is for example described in the German patent application DE 102017130779.6, which is hereby incorporated by reference.

In at least one embodiment the total internal reflection lens is arranged spaced from the optoelectronic semiconductor chip. The total internal reflection lens can be spaced from the optoelectronic semiconductor chip in such a way that the total internal reflection lens is not in direct contact with the optoelectronic semiconductor chip. For example, the total internal reflection lens can comprise a recess in which the optoelectronic semiconductor chip is arranged. In this way, electromagnetic radiation emitted by the optoelectronic semiconductor chip during operation can enter the total internal reflection lens from a medium with a refractive index which is smaller than the refractive index of the total internal reflection lens. Therefore, at least a part of the electromagnetic radiation is not reflected at a surface of the total internal reflection lens facing the optoelectronic semiconductor chip but can enter the total internal reflection lens.

Furthermore, a method for producing an optoelectronic semiconductor device is provided. With the methods described an optoelectronic semiconductor device as described above can be formed. This means that all features disclosed for the optoelectronic semiconductor device are also disclosed for the method for forming an optoelectronic semiconductor device and vice versa.

According to at least one embodiment of the method for producing the optoelectronic semiconductor device the housing is glued to the carrier. The glue can be arranged between the housing and the carrier in the vertical direction. The glue can be arranged on the top side of the carrier along at least one side surface of the carrier. It is further possible that the glue is arranged on the top side of the carrier along each side surface of the carrier. The glue can be arranged in the shape of a frame which surrounds the optoelectronic semiconductor chip laterally. The total internal reflection lens can be positioned within the housing before the housing is glued to the carrier. Therefore, the method for producing the optoelectronic semiconductor device allows a simplified alignment of the total internal reflection lens with respect to the optoelectronic semiconductor chip.

According to at least one embodiment of the method for producing the optoelectronic semiconductor device the housing and the carrier are connected in one processing step. This means, only one processing step is required to connect the housing with the carrier. As the total internal reflection lens is arranged within the housing no positioning of the total internal reflection lens is required after the housing is connected to the carrier. Advantageously, since only one processing step is required to connect the housing and the carrier the probability for a misalignment of the total internal reflection lens with respect to the optoelectronic semiconductor chip is reduced.

### BRIEF DESCRIPTION OF THE DRAWINGS

The following description of figures may further illustrate and explain exemplary embodiments. Components that are functionally identical or have an identical effect are denoted by identical references. Identical or effectively identical components might be described only with respect to the figures where they occur first. Their description is not necessarily repeated in successive figures.

FIG. 1 shows an exploded view of an optoelectronic semiconductor device;

In FIGS. 2 and 3 an optoelectronic semiconductor device is shown;

FIG. 4 shows an exploded view of an exemplary embodiment of the optoelectronic semiconductor device;

With FIGS. 5A, 5B, 5C, 6A and 6B a further exemplary embodiment of the optoelectronic semiconductor device is described;

In FIG. 7 the simulated intensity of radiation emitted by an exemplary embodiment of the optoelectronic semiconductor device is plotted; and

In FIGS. 8A, 8B and 9 an exemplary embodiment of the carrier with the optoelectronic semiconductor chip is shown.

### DETAILED DESCRIPTION OF ILLUSTRATIVE EMBODIMENTS

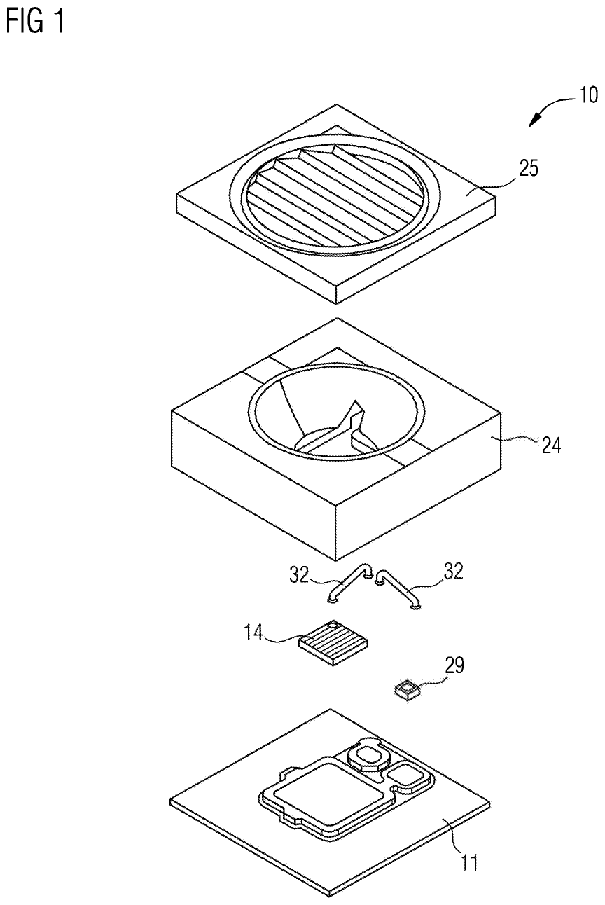

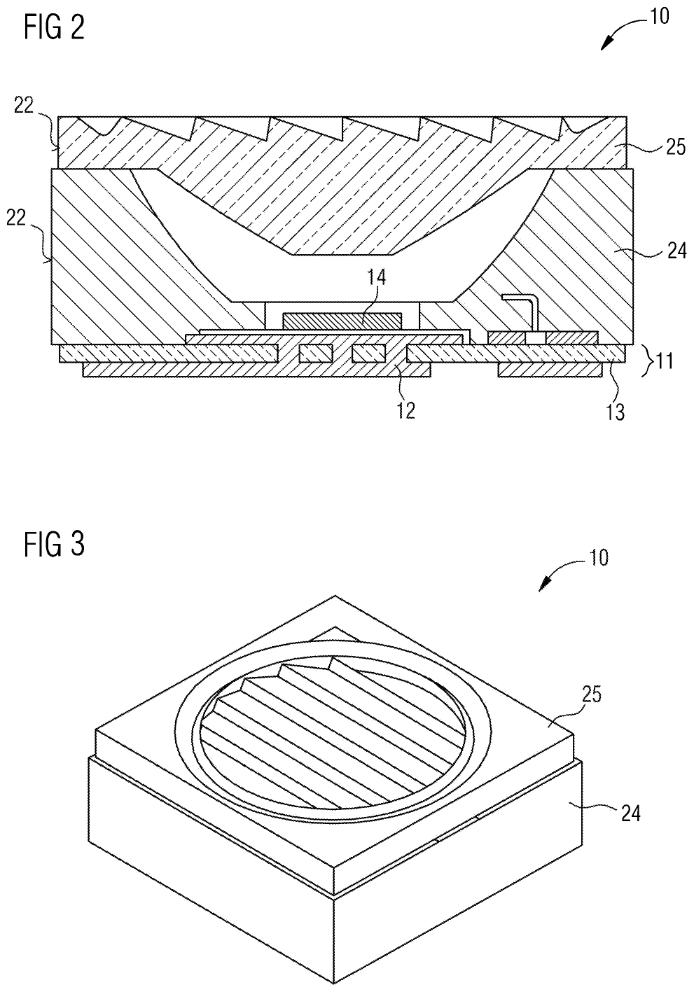

In FIG. 1 an exploded view of an optoelectronic semiconductor device 10 which is no embodiment of the optoelectronic semiconductor device 10 described herein is shown. The optoelectronic semiconductor device 10 comprises a carrier 11. On the carrier 11 an optoelectronic semiconductor chip 14 is arranged and electrically contacted via a bonding wire 32. Adjacent to the optoelectronic semiconductor chip 14 an electrostatic discharge chip 29 is arranged. Furthermore, a reflector 24 is arranged on the carrier 11. The reflector 24 comprises a recess in which the optoelectronic semiconductor chip 14 is arranged. The reflector 24 further comprises inclined inner walls that surround the optoelectronic semiconductor chip 14. The inner walls are coated with a reflective film, for example with a metal layer. On top of the reflector 24 a lens 25 is arranged.

In FIG. 2 a cutaway view of the optoelectronic semiconductor device 10 of FIG. 1 is shown. The carrier 11 is a printed circuit board which comprises electrically conductive components 12 and an electrically insulating material 13 which is arranged between the electrically conductive components 12. The electrically conductive components 12 protrude over the electrically insulating material 13. A high value of the thermal resistance of the printed circuit board can require additional components for cooling the optoelectronic semiconductor chip 14. These additional components for cooling can cause the surface of the carrier 11 on which the optoelectronic semiconductor chip 14 is arranged to be uneven such that the adhesion between the optoelectronic semiconductor chip 14 and the carrier 11 is reduced.

For the assembly of the optoelectronic semiconductor device 10 two alignment steps are required. As a first step, the reflector 24 is attached to the carrier 11. In a second step, the lens 25 is glued to the reflector 24. The lens 25 is placed on top of the reflector 24 without a mechanical positioning feature. Furthermore, the area where the glue can be arranged between the lens 25 and the reflector 24 is limited. Therefore, the adhesion between the lens 25 and the reflector 24 and might be low and the lens 25 can be exposed to shear forces because of its position on top of the reflector 24. Another issue is that the glue between the lens 25 and the reflector 24 tends to smear to side surfaces 22 of the reflector 24 and the lens 25. The glue at the side surfaces 22 increases the cross section of the optoelectronic semiconductor device 10 which can cause problems during further processing steps.

In FIG. 3 a top view on the optoelectronic semiconductor device 10 shown in FIG. 2 is shown. The lens 25 completely covers the reflector 24.

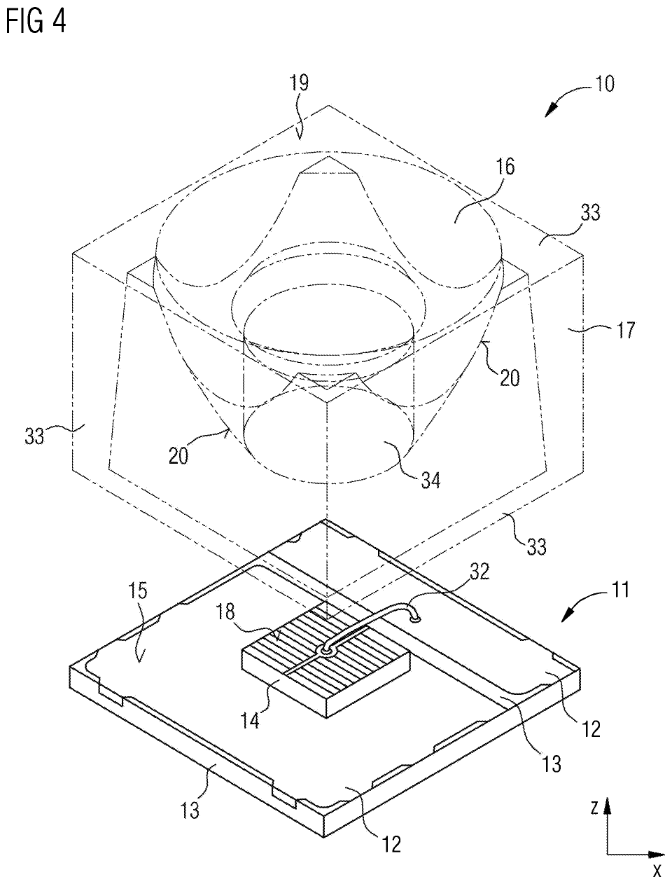

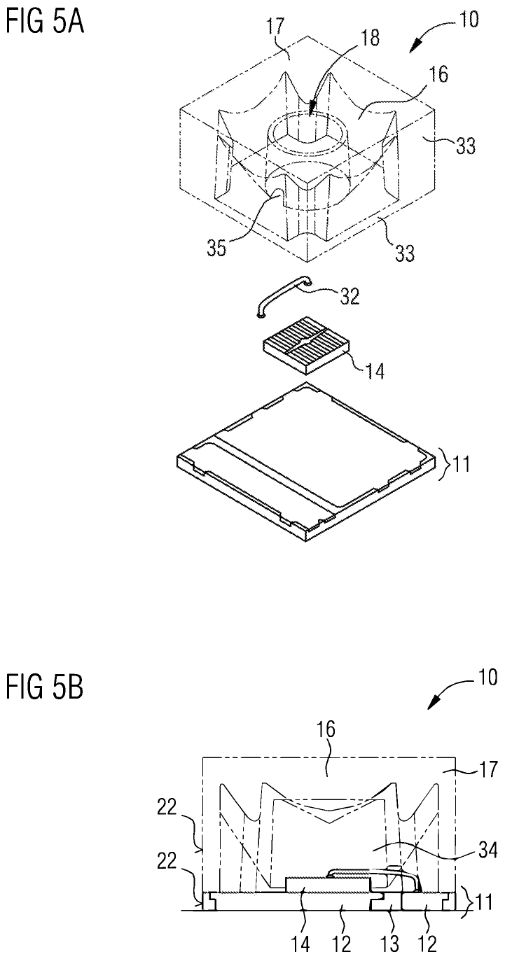

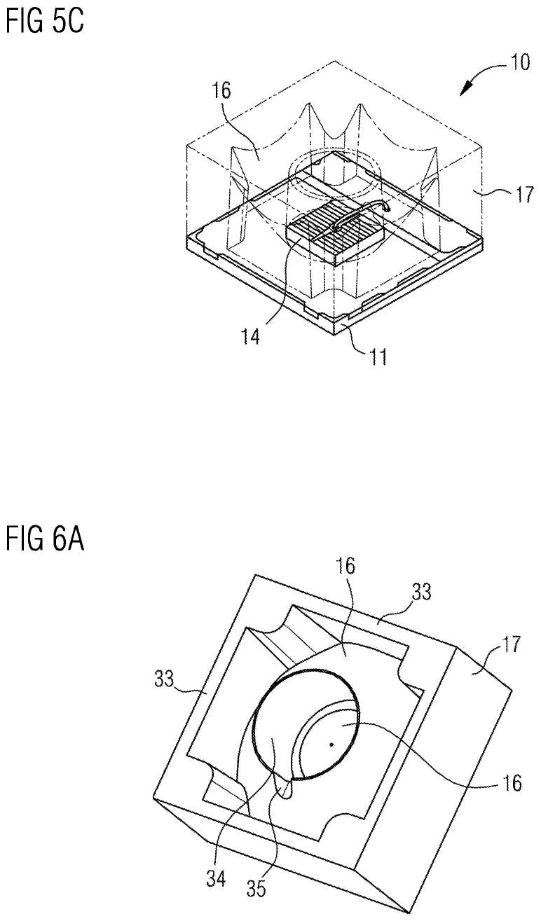

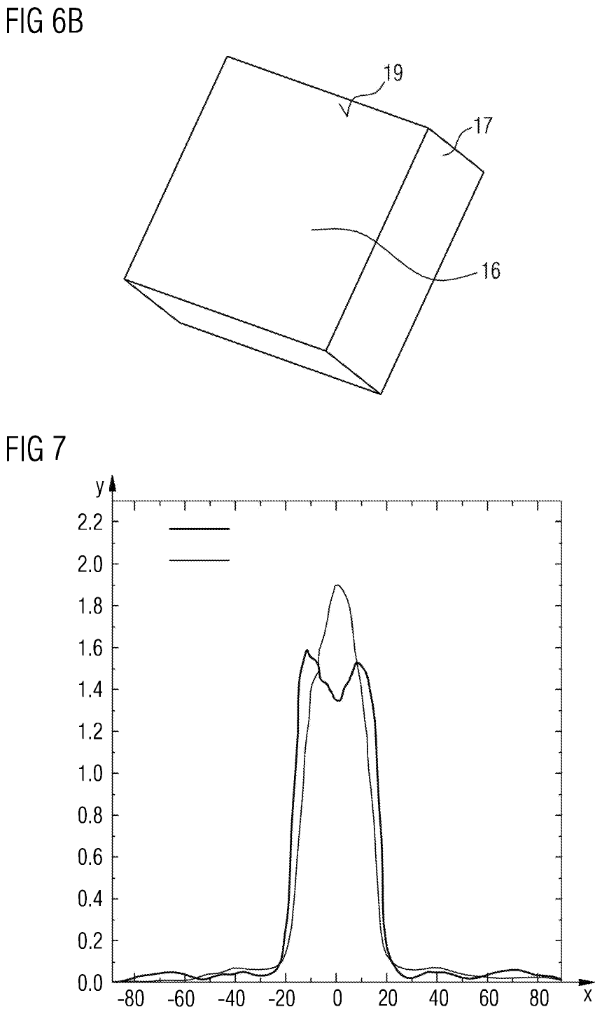

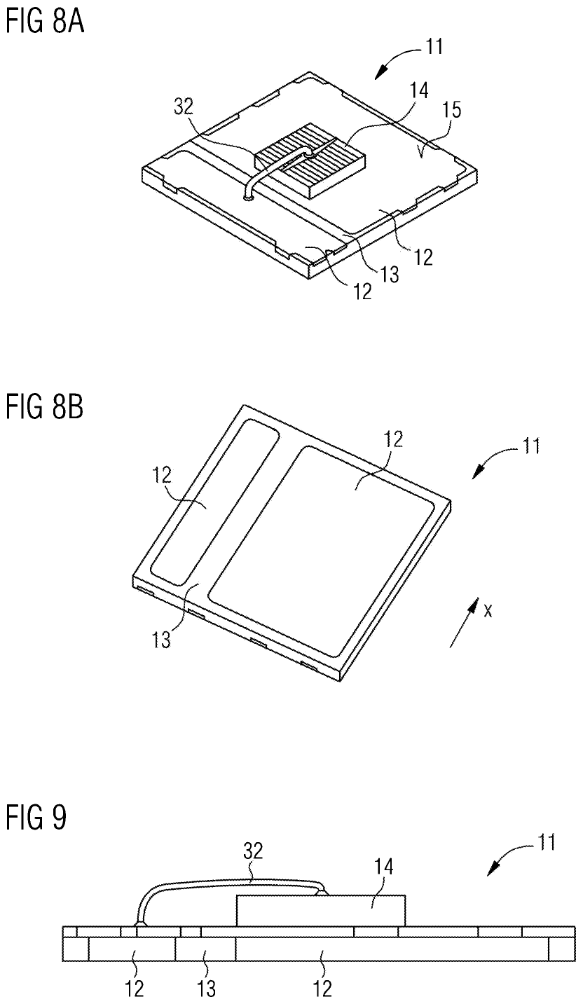

In FIG. 4 an exploded view of an exemplary embodiment of an optoelectronic semiconductor device 10 described herein is shown. The optoelectronic semiconductor device 10 comprises a carrier 11. The carrier 11 comprises two electrically conductive components 12 which are connected by an electrically insulating material 13. The two electrically conductive components 12 are electrically isolated against each other by the electrically insulating material 13. The electrically conductive components 12 can form a leadframe. The electrically insulating material 13 forms a frame which surrounds the two electrically conductive components 12 from all sides in lateral directions x, where the lateral directions x are parallel to the main plane of extension of the carrier 11. Moreover, the electrically insulating material 13 does not protrude over the electrically conductive components 12 at a top side 15 of the carrier 11. The electrically insulating material 13 terminates flush with the electrically conductive components 12 at the top side 15 of the carrier 11.

The optoelectronic semiconductor device 10 further comprises an optoelectronic semiconductor chip 14. The optoelectronic semiconductor chip 14 is fixed to the carrier 11 at the top side 15 of the carrier 11. The optoelectronic semiconductor chip 14 is configured to emit electromagnetic radiation during operation of the optoelectronic semiconductor device 10. The optoelectronic semiconductor chip 14 is arranged on one of the electrically conductive components 12. The optoelectronic semiconductor chip 14 is electrically connected with the other electrically conductive component 12 via a bonding wire 32. Furthermore, the optoelectronic semiconductor chip 14 is arranged in the center of the carrier 11 and the optoelectronic semiconductor chip 14 does not completely cover the carrier 11.

The optoelectronic semiconductor device 10 further comprises a total internal reflection lens 16 and a housing 17 which surrounds the total internal reflection lens 16 laterally. The housing 17 is arranged on the top side 15 of the carrier 11. The housing 17 and the total internal reflection lens 16 are arranged at a radiation exit side 18 of the optoelectronic semiconductor chip 14. The housing 17 comprises a recess in which the total internal reflection lens 16 is arranged. The recess extends from the side of the housing 17 at which the carrier 11 is arranged towards an upper side 19 of the optoelectronic semiconductor device 10 which faces away from the carrier 11. The total internal reflection lens 16 arranged within the recess extends from the top side 15 of the carrier 11 towards the upper side 19 as well. The housing 17 surrounds the total internal reflection lens 16 laterally. The housing 17 comprises sidewalls 33 which are arranged around the total internal reflection lens 16 as a frame. The sidewalls 33 extend at least in places in a vertical direction z which is perpendicular to the main plane of extension of the carrier 11. The sidewalls 33 of the housing 17 are connected with the carrier 11 via a glue. This means, the glue which is arranged between the housing 17 and the carrier 11 has the shape of a frame which completely surrounds the optoelectronic semiconductor chip 14. Therefore, the glue is arranged on a large area which increases the adhesion between the housing 17 and the carrier 11.

The sidewalls 33 are in places connected with the total internal reflection lens 16. The total internal reflection lens 16 is connected to the housing 17 close to the upper side 19 of the optoelectronic semiconductor device 10. A connection region is arranged in the vicinity of the upper side 19 where the total internal reflection lens 16 is connected to the housing 17. In the connection region a glue can be arranged between the housing 17 and the total internal reflection lens 16. The total internal reflection lens 16 is fixed to the housing 17 such that the total internal reflection lens 16 is monolithically integrated with the housing 17.

At the top side 15 of the carrier 11 the total internal reflection lens 16 is not connected to the housing 17. At the top side 15 of the carrier 11 the total internal reflection lens 16 is spaced from the housing 17. This means, a medium as air is arranged between the total internal reflection lens 16 and the housing 17 at the top side 15.

The total internal reflection lens 16 can comprise an epoxy resin or a plastic material. The total internal reflection lens 16 comprises a recess 34 which has the shape of a cylinder. The recess 34 of the total internal reflection lens 16 is arranged at the top side 15 of the carrier 11 and the optoelectronic semiconductor chip 14 is arranged within the recess 34. This means, the total internal reflection lens 16 and the optoelectronic semiconductor chip 14 are spaced from each other and they are not in direct contact. The total internal reflection lens 16 further comprises outer surfaces 20 which are at least partially inclined with respect to the main plane of extension of the carrier 11. The outer surfaces 20 extend from the top side 15 of the carrier 11 towards the upper side 19. The outer surfaces 20 are inclined in such a way that the cross section of the total internal reflection lens 16 increases from the top side 15 of the carrier 11 towards the upper side 19. The cross section of the total internal reflection lens 16 is circular-shaped.

At the upper side 19 of the optoelectronic semiconductor device 10 the total internal reflection lens 16 does not protrude over the housing 17. The total internal reflection lens 16 terminates flush with the housing 17 at the upper side 19 of the optoelectronic semiconductor device 10.

FIG. 4 shows that the housing 17 with the total internal reflection lens 16 can be connected with the carrier 11 within one processing step where the housing 17 is glued to the carrier 11.

As the electromagnetic radiation emitted by the optoelectronic semiconductor chip 14 during operation is shaped by the total internal reflection lens 16, the electromagnetic radiation only leaves the optoelectronic semiconductor device 10 at the upper side 19.

In FIG. 5A an exploded view of a further exemplary embodiment of the optoelectronic semiconductor device 10 is shown. As a difference to the embodiment shown in FIG. 4 the sidewalls 33 of the housing 17 comprise a larger thickness at the four corners of the housing 17. In this way, the area on which the glue between the carrier 11 and the housing 17 is arranged is enlarged in order to improve the adhesion between the carrier 11 and the housing 17. Furthermore, the total internal reflection lens 16 comprises a further recess 35 in which the bonding wire 32 is arranged.

In FIG. 5B a cutaway view of the embodiment of the optoelectronic semiconductor device 10 of FIG. 5A is shown. Side surfaces 22 of the housing 17 terminate flush with side surfaces 22 of the carrier 11. Furthermore, the total internal reflection lens 16 is not in direct contact with the carrier 11. This means, the total internal reflection lens 16 is only fixed to the housing 17. The recess 34 of the total internal reflection lens 16 comprises a top side 15 at which the total internal reflection lens 16 protrudes into the recess 34. The total internal reflection lens 16 protrudes into the recess 34 in the shape of a cone.

FIG. 5C shows the embodiment of the optoelectronic semiconductor device 10 of FIG. 5A. The housing 17 with the total internal reflection lens 16 is fixed to the carrier 11.

In FIG. 6A the embodiment of the housing 17 of FIG. 5A is shown from the side of the carrier 11. The sidewalls 33 of the housing 17 laterally surround the total internal reflection lens 16. The total internal reflection lens 16 comprises the recess 34 and the further recess 35. The total internal reflection lens 16 protrudes into the recess 34 in the shape of a cone.

In FIG. 6B the embodiment of the housing 17 of FIG. 6A is shown from the upper side 19. At the upper side 19 the housing 17 terminates flush with the total internal reflection lens 16.

In FIG. 7 the simulated intensity of electromagnetic radiation emitted by the optoelectronic semiconductor device 10 according to one embodiment is plotted. On the x-axis the angle measured with respect to the vertical direction z is plotted in degrees. On the y-axis the intensity is plotted in Watt per steradian. The bold line refers to the simulated intensity of electromagnetic radiation emitted by the optoelectronic semiconductor device 10 shown in FIGS. 1 to 3. The other line refers to the simulated intensity of electromagnetic radiation emitted by an embodiment of the optoelectronic semiconductor device 10 shown in FIGS. 4 to 6B. The opening angle of the emitted electromagnetic radiation is similar for both devices. The intensity of the emitted electromagnetic radiation is larger for the embodiment of the optoelectronic semiconductor device 10 shown in FIGS. 4 to 6B.

In FIG. 8A an exemplary embodiment of the carrier 11 is shown. At the top side 15 the optoelectronic semiconductor chip 14 is arranged. The optoelectronic semiconductor chip 14 is arranged on one of the electrically conductive components 12 and it is connected to the other electrically conductive component 12 via the bonding wire 32.

In FIG. 8B the exemplary embodiment of the carrier 11 of FIG. 8A is shown from the side facing away from the top side 15. The two electrically conductive components 12 and the electrically insulating material 13 extend through the whole carrier 11. The electrically conductive components 12 are arranged next to each other and they are electrically isolated against each other by the electrically insulating material 13. The electrically insulating material 13 completely surrounds the electrically conductive components 12 as a frame in lateral directions x.

In FIG. 9 a cutaway view of the exemplary embodiment of the carrier 11 of FIGS. 8A and 8B is shown.

The description with the aid of the exemplary embodiments does not limit the invention thereto. Rather, the invention comprises any new feature and any combination of features, which in particular includes any combination of features in the patent claims, even if this feature or this combination is not itself explicitly stated in the patent claims or exemplary embodiments.

1-14. (canceled)

15. An optoelectronic semiconductor device comprising:
a carrier comprising at least two electrically conductive components connected by an electrically insulating material;
an optoelectronic semiconductor chip fixed to the carrier at a top side of the carrier, the optoelectronic semiconductor chip configured to emit electromagnetic radiation;
a total internal reflection lens; and
a housing surrounding the total internal reflection lens laterally,
wherein the electrically insulating material does not protrude over the electrically conductive components at the top side of the carrier,
wherein the housing and the total internal reflection lens are arranged at a radiation exit side of the optoelectronic semiconductor chip, and
wherein the total internal reflection lens does not protrude over the housing at an upper side of the optoelectronic semiconductor device, the upper side facing away from the carrier.

16. The optoelectronic semiconductor device according to claim 15, wherein the total internal reflection lens is monolithically integrated with the housing.

17. The optoelectronic semiconductor device according to claim 15, wherein electromagnetic radiation only leaves the optoelectronic semiconductor device at the upper side.

18. The optoelectronic semiconductor device according to claim 15, wherein the total internal reflection lens comprises outer surfaces which are at least partially inclined with respect to a main plane of extension of the carrier.

19. The optoelectronic semiconductor device according to claim 15, wherein at least a part of a radiation exit surface of the total internal reflection lens is spherical, aspherical or elliptical.

20. The optoelectronic semiconductor device according to claim 15, wherein the carrier comprises a leadframe.

21. The optoelectronic semiconductor device according to claim 15, wherein a side surface of the housing terminates flush with a side surface of the carrier.

22. The optoelectronic semiconductor device according to claim 15, wherein the housing is fixed to the carrier by glue.

23. The optoelectronic semiconductor device according to claim 15, wherein the total internal reflection lens comprises an epoxy resin.

24. The optoelectronic semiconductor device according to claim 15, wherein the total internal reflection lens comprises a plastic material.

25. The optoelectronic semiconductor device according to claim 15, wherein an opening angle of a beam of the electromagnetic radiation is smaller than 30°.

26. The optoelectronic semiconductor device according to claim 15, wherein the total internal reflection lens is spaced apart from the optoelectronic semiconductor chip.

27. A method for producing the optoelectronic semiconductor device according to claim 15, the method comprising:
gluing the housing to the carrier.

28. The method according to claim 27, wherein the housing and the carrier are connected in one processing step.

29. An optoelectronic semiconductor device comprising:
a carrier comprising at least two electrically conductive components connected by an electrically insulating material;
an optoelectronic semiconductor chip fixed to the carrier at a top side of the carrier, the optoelectronic semiconductor chip configured to emit electromagnetic radiation;
a total internal reflection lens; and
a housing surrounding the total internal reflection lens laterally,
wherein the electrically insulating material does not protrude over the electrically conductive components at the top side of the carrier,
wherein the housing and the total internal reflection lens are arranged at a radiation exit side of the optoelectronic semiconductor chip,
wherein the total internal reflection lens does not protrude over the housing at an upper side of the optoelectronic semiconductor device, the upper side facing away from the carrier, and
wherein a side surface of the housing terminates flush with a side surface of the carrier.
